(19) United States
(12) Patent Application Publication
(10) Pub. No.: US 2025/0218795 A1
(43) Pub. Date: Jul. 3, 2025

(54) METHOD FOR MANUFACTURING PACKAGE SUBSTRATE

(71) Applicant: PHOENIX PIONEER TECHNOLOGY CO., LTD., Hsinchu County (TW)

(72) Inventors: YING-TUNG WANG, Hsinchu County (TW); SHIH-PING HSU, Hsinchu County (TW)

(21) Appl. No.: 18/954,574

(22) Filed: Nov. 21, 2024

(30) Foreign Application Priority Data
Dec. 28, 2023 (TW) 112151203

(51) Int. Cl. H01L 21/48; H01L 23/00; H01L 23/31; H01L 23/498

(52) U.S. Cl. CPC H01L 21/4857; H01L 23/49822; H01L 23/3121; H01L 24/48; H01L 2224/48155; H01L 2924/1517

(57) ABSTRACT

A method of manufacturing a package substrate, which mainly uses an adhesive material to bond two metal sheets to each other to form a circuit base-material board with sufficient rigidity. In addition to eliminating the need for a carrier board to save production costs, the method can also perform pattern development, etching, RCC lamination (Resin Coated Copper) and other manufacturing processes on both sides of the circuit base-material board simultaneously to produce a package substrate with a single layer of circuits, and can effectively and significantly improve the production efficiency and capacity of package substrate.

### CROSS REFERENCE TO RELATED APPLICATION

This application claims the benefits of Taiwan application Serial No. 112151203, filed on Dec. 28, 2023, the disclosures of which are incorporated by references herein in its entirety.

### TECHNICAL FIELD

The present disclosure relates to a method for manufacturing a package substrate, particularly a manufacturing method for simultaneously producing two package substrates having a single layer of circuits.

### BACKGROUND

The main function of the packaging substrate is to realize the electrical interconnection between the circuit and electronic components outside the chip of the integrated circuit. Package substrates can be categorized into core packaging substrates and coreless packaging substrates according to the different manufacturing methods.

The structure of the core package substrate can be mainly divided into the core board in the middle portion, and the laminate board in the upper and lower portions. The manufacturing method of core package substrate is through high-density interconnected printed circuit board technology.

Compared with the core package substrate, the coreless package substrate eliminates the use of the core board in the middle portion. The new manufacturing method of the coreless package substrate mainly utilizes the bottom-up electroplating deposition method to create the copper column conductive structure between the layers of the carrier board.

Since coreless package carriers do not utilize a core board, it is often necessary to start manufacturing with a rigid carrier to carry the subsequent plating deposition process and insulation layer process. The internal laminated circuit interconnect structure of a coreless package carrier board consists mainly of copper pillars and wires. The technical characteristics of the manufacturing method for the coreless package surface are mainly to form the interconnection structures in the package substrate, such as copper pillars and wires, by depositing copper metal from the bottom to the top on a rigid carrier board by electroplating deposition technology according to the planned circuit pattern. Since the copper posts made in this method are solid copper metal pillar structures, they have better performance in electrical transmission.

After the circuit lamination for the package substrate is completed, the carrier board must be removed to obtain a package substrate.

Since the carrier is used to carry the laminate in the manufacturing process of the package substrate, it is inevitable to use the carrier for production in the common manufacturing methods. However, the cost of the carrier is very high, and it is undoubtedly a great progress in terms of production cost if the use of the carrier plate for production can be avoided.

### SUMMARY

In view of the above-mentioned problems and their root causes, specific and feasible solutions are proposed by the inventor of the present disclosure. The present disclosure provides a manufacturing method of the package substrate that does not require the use of a carrier, particularly a manufacturing method of a package substrate for a Quad Flat No-lead Package (QFN). The inventor of the present disclosure uses an adhesive material to adhesively bond two metal sheets to each other to form a circuit base-material board with sufficient rigidity. Since the price of the adhesive material is much lower than that of the carrier, the cost for using the carrier is eliminated. Afterwards, subsequent manufacturing processes, such as pattern development, etching, and RCC (Resin Coated Copper) lamination are executed on the circuit base-material board to form a package substrate with a single layer of circuits.

In addition, the method for manufacturing the package substrate in the present disclosure uses two metal plates bonded to each other with an adhesive material as a circuit base-material board for manufacturing the package substrate. Therefore, the biggest difference between the manufacturing method of the present disclosure and the conventional methods is that, in addition to saving costs by not using a carrier, more importantly, the manufacturing method of the present disclosure processes and fabricates two metal plates simultaneously. Therefore, the manufacturing method can produce two package substrates simultaneously. Compared with the conventional manufacturing method of producing one package substrate at a time, the production capacity can be greatly increase.

The present disclosure proposes a method for manufacturing a package substrate, comprising: providing a circuit base-material board made by two metal plates and an adhesive material bonded together; implementing a first development process to form a patterned first protection layer on each of the second surfaces of the two metal plates; implementing a first etching process by etching to remove metal material on each of the second surfaces of the two metal plates that is not covered by the first protection layer to form a plurality of first openings; implementing a second etching process for etching to remove the first protection layer to expose each of the second surfaces of the two metal plates; implementing a lamination process to perform lamination with an insulating film material having a metal surface on one side surface on the two metal plates and fill each of the first openings by the insulating film material; implementing a second development process to form a patterned second protection layer on the metal surface of each of the insulating film layers; implementing a third etching process for etching to remove metal material on the metal surface of the area on each of the insulating film layers that is not covered by the second protection layer, wherein the metal surface covered by the second protection layer serves as a patterned third protection layer; implementing a fourth etching process for etching to remove the second protection layer and a portion of the insulating film layer to expose the third protection layer; implementing a fifth etching process for etching to remove the third protection layer; implementing a board removal process to separate the two metal plates from the adhesive material and obtain two package substrate semi-finished products; implementing a third development process to form a patterned fourth protection layer on the first surface of the metal plate in the package substrate semi-finished product; implementing a surface treatment process to form a patterned surface treatment layer on a metal surface area that is not covered by the fourth protection layer; implementing a sixth etching process for etching to remove the fourth protection layer and expose metal surface that is not covered by the surface treatment layer on the metal plate; and implementing a seventh etching process for etching to remove the metal material of the metal plate in an area that is not covered by the surface treatment layer to form a plurality of second openings connected to a plurality of first openings to obtain a package substrate with a single layer of circuits.

According to an embodiment of the method for manufacturing the package substrate of the present disclosure, the material of the first protection layer, the second protection layer or the fourth protection layer is a dry film, a photosensitive resin composition or a photosensitive resin film.

According to an embodiment of the method for manufacturing the package substrate of the present disclosure, the board removal process further comprises performing a high-temperature baking process or a low-temperature baking process before separating the two metal plates from the adhesive material.

According to an embodiment of the method for manufacturing the package substrate of the present disclosure, the material of the surface treatment layer is non-copper material. In a preferred embodiment, the material of the surface treatment layer is nickel, palladium, platinum, gold or a combination thereof, or an alloy thereof.

### BRIEF DESCRIPTION OF THE DRAWINGS

FIGS. 1 to 8 are schematic cross-sectional views illustrating the structure of each step in the manufacturing method of the package substrate according to the present disclosure.

FIG. 1 is a schematic cross-sectional view of the structure of a circuit base-material board in the manufacturing method of the package substrate according to the present disclosure.

FIG. 2 is a schematic cross-sectional view of the structure after performing the first development process and the first etching process in the manufacturing method of the package substrate according to the present disclosure.

FIG. 3 is a schematic cross-sectional view of the structure after performing the lamination process in the manufacturing method of the package substrate according to the present disclosure.

FIG. 4 is a schematic cross-sectional view of the structure after performing the second development process in the manufacturing method of the package substrate according to the present disclosure.

FIG. 5 is a schematic cross-sectional view of the structure after performing the second etching process in the manufacturing method of the package substrate according to the present disclosure.

FIG. 6 is a schematic cross-sectional view of the structure of two package substrate semi-finished products obtained after performing a board removal process in the manufacturing method of the package substrate according to the present disclosure.

FIG. 7 is a schematic cross-sectional view of the structure after performing the third development process and the surface treatment process in the manufacturing method of the package substrate of the present disclosure.

FIG. 8 is a schematic cross-sectional view of the package substrate structure obtained after performing the third etching process in the manufacturing method of the package substrate of the present disclosure.

FIG. 9 is a schematic diagram of an embodiment of the package substrate of the present disclosure applied to semiconductor package.

### DETAILED DESCRIPTION

The manufacturing method of the package substrate disclosed herein and an embodiment of the package substrate obtained according to the manufacturing method are described below with reference to the relevant drawings, which may be exaggerated or reduced in size or scale for the sake of clarity and ease of graphical illustration. For ease of understanding, the same components or steps in the following embodiments are illustrated by the same symbols.

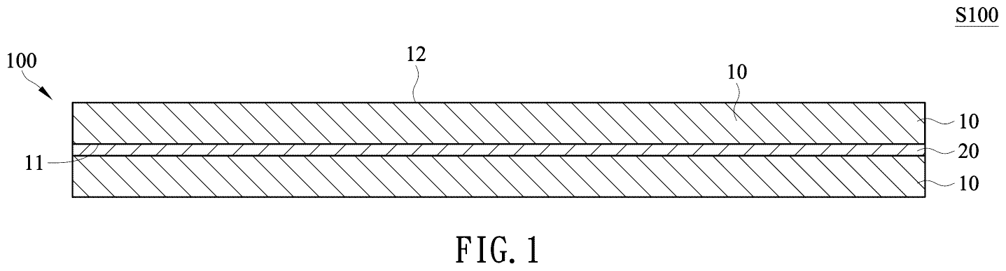

Please refer to FIGS. 1 to 8, which are schematic cross-sectional views illustrating the structure of each step in a method for method for manufacturing the package substrate according to the present disclosure. The manufacturing method of the package substrate according to the present disclosure at least includes the following steps. Step S100: provide a circuit base-material board 100. Step S200: implement a first development process and implement a first etching process to form a plurality of first opening. Step S300: implement a lamination process to fill each first opening with an insulating material by using the RCC lamination. Step S400: implement a second development process and implement a third etching process to remove a portion of the metal surface on the RCC lamination. Step S500: implement a fourth etching process and implement a fifth etching process to remove a portion of the insulating material and all of the metal surface of the RCC lamination. Step S600: implement a board removal process to form two package substrate semi-finished products. Step S700: implement a third development process and implement a surface treatment process to form a fourth protection layer and a surface treatment layer. Step S800: implement a sixth etching process and implement a seventh etching process to form a plurality of second openings connected to the plurality of first openings, thereby obtaining a package substrate with a single layer of circuits produced according to the manufacturing method of the present disclosure.

Detailed description is provided as follows. First, please refer to FIG. 1. In the method of manufacturing a package substrate according to the present disclosure, in step S100 (as shown in FIG. 1), a circuit base-material board 100 is provided as a starting piece of the package substrate to start the manufacturing of the package substrate with the structure as shown in FIG. 1. The circuit base-material board 100 includes two metal plates 10 (for example, copper metal plates) and an adhesive material 20. Each of the two metal plates has a first surface 11 and a second surface 12 opposite each other. The adhesive material 20 is disposed between the two metal plates 10 and is adhesively bonded to the first surfaces 11 of the two metal plates 10. In other words, as can be seen from the structure shown in FIG. 1, the circuit base-material board 100 is a multilayer structure formed by adhering and laminating the two metal plates 10 to be processed to each other. By using a cheap adhesive material 20 to adhere the two metal plates 10 to each other, the circuit base-material board 100 formed can have considerable rigidity, so that it will not be deformed even if the manufacturing process of the package substrate is carried out without using the carrier, and the cost of using the carrier can be reduced. In addition, by simultaneously performing the manufacturing process on the two metal plates 10 of the circuit base-material board 100, two package substrates can be produced at one time. Compared to the conventional method of producing one piece at a time and having to use a carrier, the manufacturing method of the package substrate disclosed herein can greatly increase the production capacity and reduce the cost.

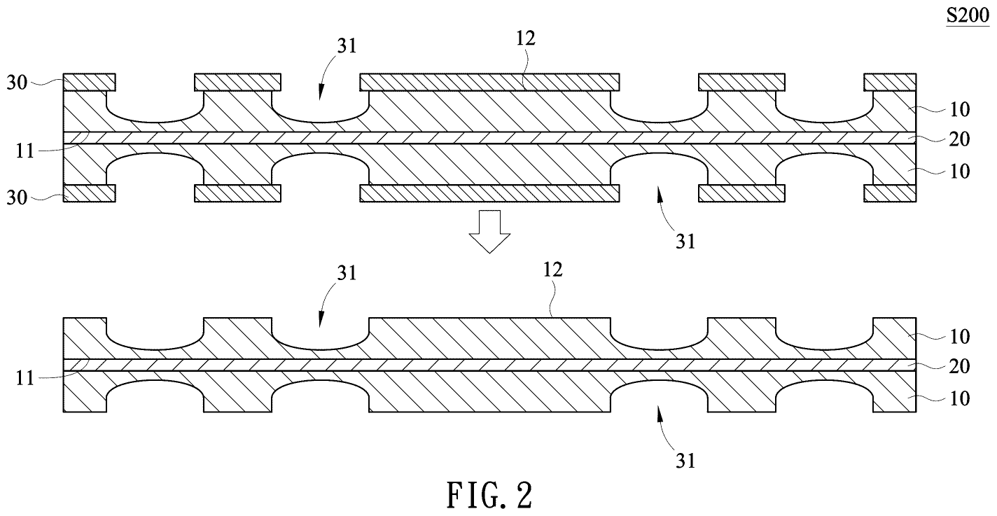

Next, please refer to FIG. 2. In the method for method for manufacturing the package substrate according to the present disclosure, step S200 (as shown in FIG. 2) includes implementing a first development process, implementing a first etching process, and implementing a second etching process. Implementing the first development process includes: forming a patterned first protection layer 30 on each second surface 12 of the two metal plates 10 of the circuit base-material board 100. Afterwards, implementing a first etching process, which includes: etching to remove the metal material (such as copper metal) on each second surface 12 of the two metal plates 10 that is not covered by the first protection layer 30 to form a plurality of first openings 31. Afterwards, implementing a second etching process, which includes: etching to remove the first protection layer 30 to expose each second surface 12 of the two metal plates 10.

In an embodiment of the method for method for manufacturing the package substrate according to the present disclosure, the material of the first protection layer 30 is a dry film, a photosensitive resin composition or a photosensitive resin film.

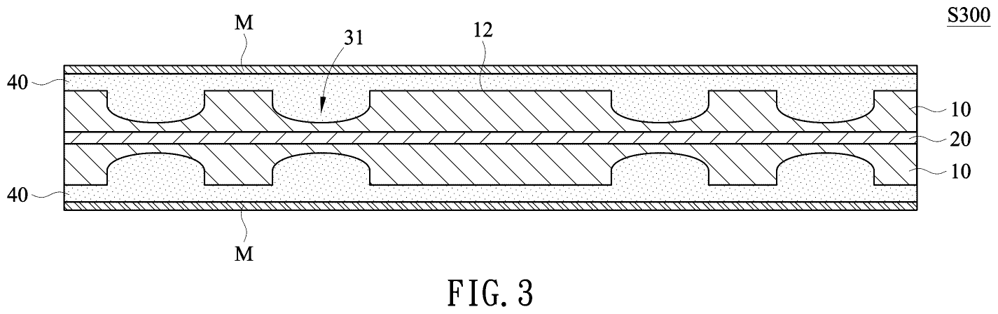

Next, please refer to FIG. 3. In the method for method for manufacturing the package substrate according to the present disclosure, step S300 (as shown in FIG. 3) includes: implementing a lamination process, which includes: on each second surface 12 of the two metal plates 10, performing lamination (RCC lamination) with an insulating film material having a metal surface on one side surface to form an insulating film layer 40 on each second surface. The outer surface of the insulating film layer 40 has a metal surface M, and the insulating film layer 40 covers on each second surface 12 and fills each first opening 31. Among them, the insulating material is composed of dielectric materials, such as ABF (Ajinomoto Build-up Film), photosensitive resin, Polyimide (PI), Bismaleimide Triazine (BT), FR5 prepreg (PP for short), Molding Compound, Epoxy Molding Compound (EMC) or other appropriate materials.

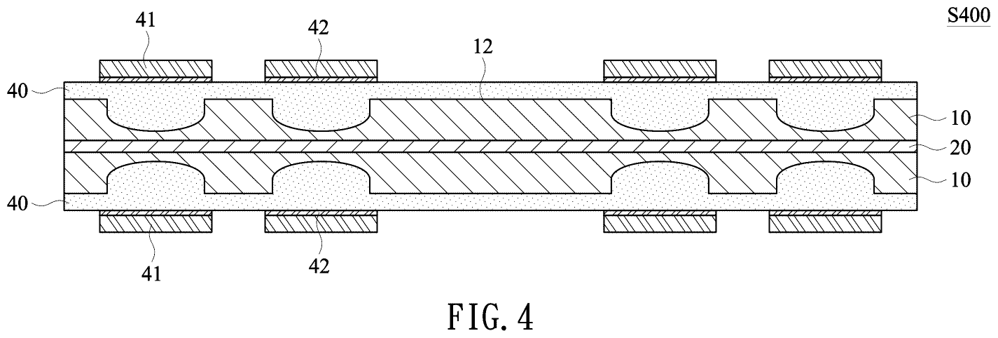

Next, please refer to FIG. 4. In the method for manufacturing the package substrate according to the present disclosure, step S400 (as shown in FIG. 4) includes: implementing a second development process, which includes: forming a patterned second protection layer 41 on the metal surface M of each insulating film layer 40. Amont them, the area covered by each second protection layer 41 on each insulating film layer 40 corresponds to each first opening 31. In the step, the purpose of forming the patterned second protection layer 41 is to retain only the insulating film layer 40 and its metal surface M located relative to the area of each first opening 31, and to remove the area of metal surface M that is not covered by the second protection layer 41. Therefore, by forming the patterned second protection layer 41, the second protection layer 41 is formed on the insulating film layer 40 located in the area of each first opening 31, thereby protecting the insulating film layer 40 and its metal surface M of this area to avoid being removed in the subsequent etching process. Afterwards, implementing a third etching process, which includes: etching to remove the metal material of the metal surface M in the area of each insulating film layer 40 that is not covered by the second protection layer 41, to expose the insulating surface of the insulating film layer 40 of the corresponding position. The metal surface M covered by the second protection layer 41 further serves as a patterned third protection layer 42.

In an embodiment of the method for manufacturing the package substrate according to the present disclosure, the material of the second protection layer 41 is a dry film, a photosensitive resin composition or a photosensitive resin film.

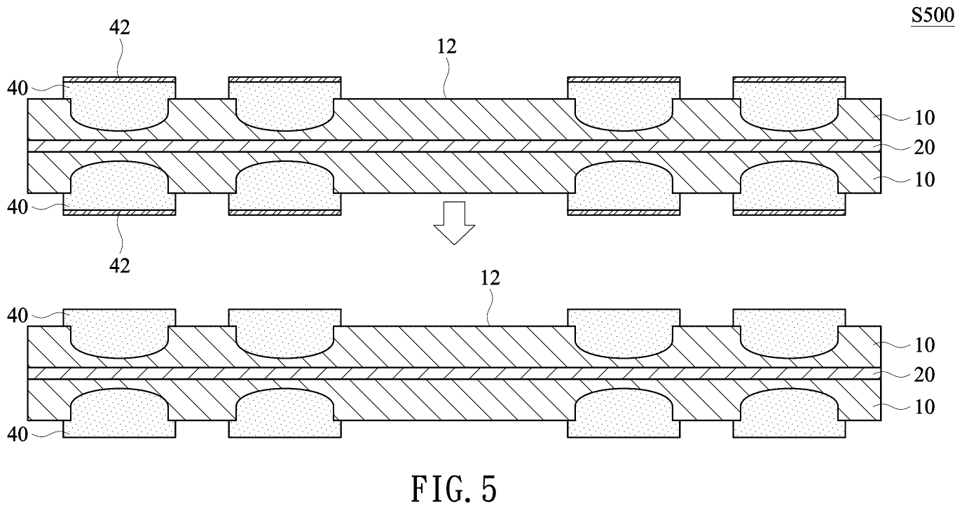

Next, please refer to FIG. 5. In a method for manufacturing the package substrate according to the present disclosure, step S500 (as shown in FIG. 5) includes: implementing a fourth etching process, which includes: etching to remove the second protection layer 41 and the exposed insulating surface of the insulating film layer 40 (i.e., the area not covered by the third protection layer 42) to expose each second surface 12 of the third protection layer 42 and the two metal plates 10 outside the positions corresponding to the first openings 31. Afterwards, implementing a fifth etching process, which includes: etching to remove the third protection layer 42 to expose the insulating surface of the insulating film layer 40 at corresponding positions originally covered by the third protection layer 42. The exposed second surface 12 will also be slightly removed by etching, but the overall structural integrity will not be affected.

In an embodiment of the method for manufacturing the package substrate of the present disclosure, the third protection layer 42 is made of copper metal.

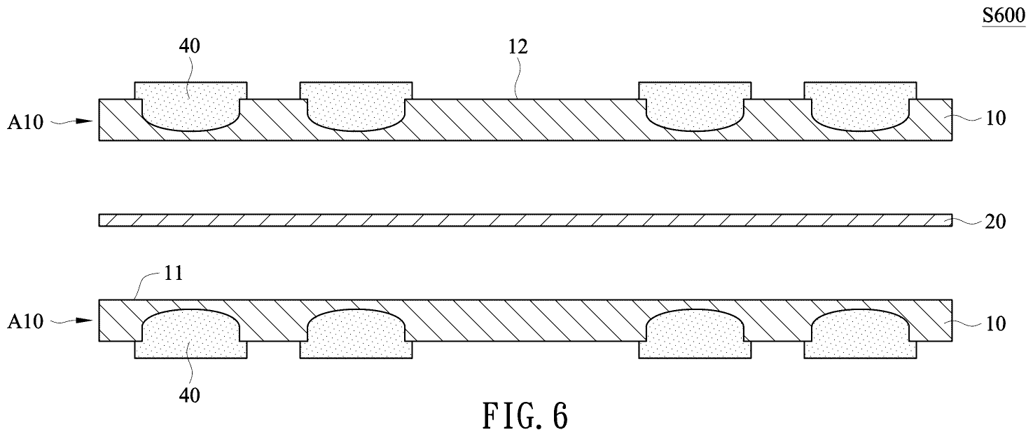

Next, please refer to FIG. 6. In the method for manufacturing the package substrate according to the present disclosure, step S600 (as shown in FIG. 6) includes: implementing a board removal process, which includes: separating the two metal plates 10 from the adhesive material 20 to obtain two package substrate semi-finished products A10. In other words, after the above steps, a plurality of first openings 31 have been formed on the second surfaces 12 of the two metal plates 10 of the circuit base-material board 100, and the insulating film layer 40 covers and fills each of the first openings 31. As shown in FIG. 6, the area covered by the insulating film layer 40 on the first opening 31 is larger than the first opening 31. After the board removal process of step S600, the semi-finished products A10 of two package substrates can be obtained. As shown in FIG. 6, the first surface 11 of the semi-finished product A10 of the package substrate is a completely unprocessed metal surface. In other words, in the manufacturing method of the package substrate of the present disclosure, the two second surfaces 12 of the two metal plates 10 are first processed together. After the process is completed, the two metal plates 10 are separated and the first surface 11 of the two metal plates 10 are processed.

The board removal process in step S600 further includes performing a high-temperature baking or low-temperature baking step before separating the two metal plates 10 from the adhesive material 20. It should be understood that the baking temperature selected in the embodiment is related to the adhesive material 20 in use. Persons of ordinary skill in the art of the disclosure can select the baking temperature according to the selected adhesive material 20 to easily separate the two metal plates 10 and the adhesive material 20, which will not be described in detail.

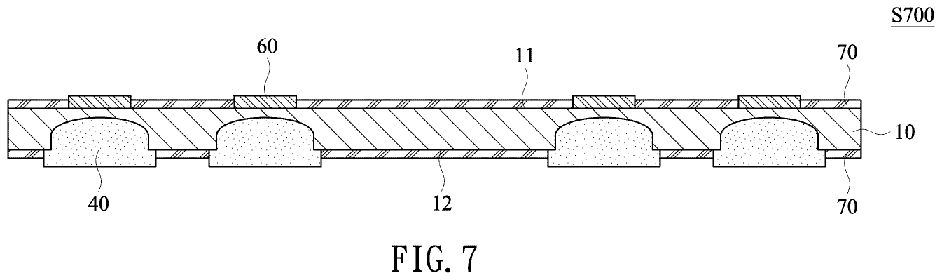

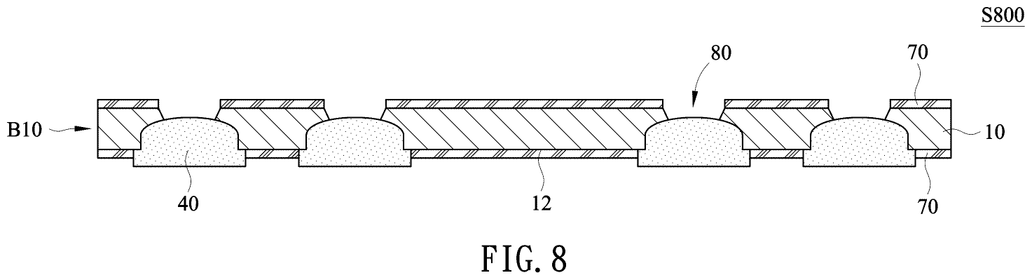

Next, please refer to FIG. 7. In the method for manufacturing the package substrate according to the present disclosure, step S700 (as shown in FIG. 7) includes implementing a third development process and a surface treatment process. Implementing the third development process includes: forming a patterned fourth protection layer 60 on the exposed first surfaces 11, and the area covered the fourth protection layer 60 on the first surface 11 corresponds to each of the first openings 31 of the second surface 12. Implementing a surface treatment process includes: forming a patterned surface treatment layer 70 on the exposed metal surface areas on the first surface 11 and the second surface 12. The composition of the surface treatment layer 70 is non-copper metal (for example, nickel, palladium, platinum, gold or combinations thereof, or alloys thereof). For further explanation, the main purpose of step S700 is to enable subsequent processes to form a plurality of second openings 80 (as shown in FIG. 8) on the first surface 11 of the metal plate 10 (for example, copper metal). Therefore, in step S700, a third development process is first used to form the fourth protection layer 60 on the first surface 11 at a position corresponding to the first opening 31 on the second surface 12. Afterwards, a surface treatment layer 70 is formed on the metal surface not covered by the fourth protection layer 60 (including the first surface 11 and the second surface 12). It should be understood that the composition of the surface treatment layer is different from the material of the metal plate 10. Therefore, when etching is performed to remove a portion of the material of the metal plate 10, the surface treatment layer 70 will not be removed simultaneously.

In an embodiment of the method for manufacturing the package substrate according to the present disclosure, the material of the fourth protection layer 60 is a dry film, a photosensitive resin composition or a photosensitive resin film.

Next, please refer to FIG. 8. In the method for manufacturing the package substrate according to the present disclosure, step S800 (as shown in FIG. 8) includes: implementing a sixth etching process, which includes: etching to remove the fourth protection layer 60, in order to expose the metal surface of the first surface 11 of the plate 10 that is not covered by the surface treatment layer 70. Afterwards, a seventh etching process is implemented, which includes: etching to remove the metal material of the first surface 11 of the metal plate 10 that is not covered by the surface treatment layer 70, in order to form a plurality of second openings 80. The bottom of each second opening 80 is connected with the bottom of each first opening 31 at its corresponding position. The insulating film layer 40 filled in each first opening 31 is exposed at the bottom of each second opening 80 at its corresponding position, so as to obtain a package substrate B10 with a single layer of circuits formed from the metal plate 10.

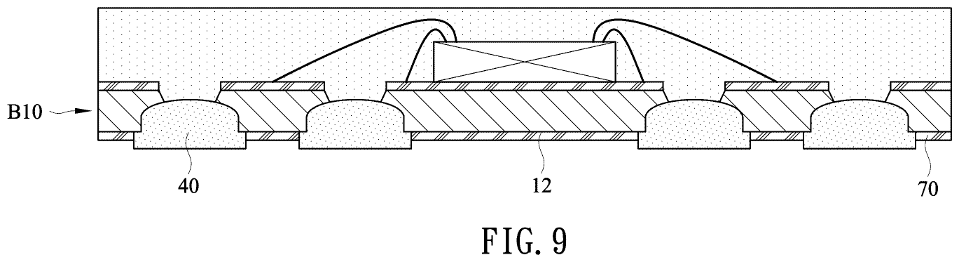

Please refer to FIG. 9, which is a schematic diagram of an embodiment of the package substrate of the present disclosure applied to a semiconductor package. As shown in FIG. 9, when the package substrate B10 obtained according to the manufacturing method of the present disclosure is used for semiconductor package, the chip to be packaged can be placed on the chip placement area of the first surface 11 of the package substrate B10, then the chip is electrically connected to a single layer of circuits formed by the metal plate 10 through wire bonding, and finally the entire chip is packaged with the insulating material.

Of course, any of the above embodiments is only for illustrative purposes and is not intended to limit the scope of the present disclosure. Equivalent modifications or variations based on one of the manufacturing methods of the package substrate described in the present embodiments should still be included in the patent scope of the present disclosure.

Based on the foregoing, in the general coreless package substrate production process, the carrier substrate must be used as a support for electroplated copper pillars or laminated circuits, and then the carrier substrate is removed and discarded when the process is completed. In addition, the production of package substrates using carrier substrates in the normal way requires not only the use of carrier substrates, but also the production of only one piece at a time. The disclosure proposes a manufacturing method for a package substrate. By bonding two metal plates with inexpensive adhesive material to form a circuit base-material board with sufficient rigidity for production. Not only can the cost of using the carrier substrate and the subsequent disposal cost of the carrier substrate be reduced, but also the simultaneous production process can be executed for two metal plates at a time and the package substrate with a single layer of circuits can be manufactured by using technically proficient processes such as developing and etching. Overall, the proposed manufacturing method of the package substrate can greatly increase the production capacity and reduce the production cost, and the process technology is more mature and stable. Compared with the existing methods, the proposed method of manufacturing the package substrates has significant advantages.

It can be seen that the present disclosure is a breakthrough from the previous technology and has achieved the desired improvement, and it is not easy for those who are familiar with the technology to think of, and its progress and practicality obviously meet the requirements for patent application. The patent application is filed in accordance with the law, and it is earnestly requested that the office approve the application for a patent for the invention, in order to encourage the creation of the invention, with truly gratefulness.

The foregoing is by way of example only and is not intended to be limiting. Any other equivalent modifications or alterations not departing from the spirit and scope of this disclosure should be included in the scope of the attached patent application.

What is claimed is:

1. A method for manufacturing a package substrate, comprising:
providing a circuit base-material board, wherein the circuit base-material board comprises two metal plates and an adhesive material, each of the two metal plates has a first surface and a second surface opposite each other, the adhesive material is provided between the two metal plates and is adhesively bonded to each of the first surfaces of the two metal plates;
implementing a first development process, which comprises: forming a patterned first protection layer on each of the second surfaces of the two metal plates;
implementing a first etching process, which comprises: etching to remove metal material on each of the second surfaces of the two metal plates that is not covered by the first protection layer to form a plurality of first openings;
implementing a second etching process, which comprises: etching to remove the first protection layer to expose each of the second surfaces of the two metal plates;
implementing a lamination process, which includes: on each of the second surfaces of the two metal plates, performing lamination with an insulating film material having a metal surface on one side surface to form an insulating film layer on each of the second surfaces, wherein an outer surface of the insulating film layer has a metal surface, and the insulating film layer covers each of the second surfaces and fills each of the first openings;
implementing a second development process, which includes: forming a patterned second protection layer on the metal surface of each of the insulating film layers, wherein an area covered by each of the second protection layers on the metal surface of each of the insulating film layers corresponds to each of the first openings;
implementing a third etching process, which includes: etching to remove metal material on the metal surface of the area on each of the insulating film layers that is not covered by the second protection layer, to expose insulation surface of the insulating film layer at the corresponding position, wherein the metal surface covered by the second protection layer serves as a patterned third protection layer;
implementing a fourth etching process, which includes: etching to remove the second protection layer and insulating surface exposed from the insulating film layer, to expose surface at corresponding position on each of the second surfaces of the two metal plates;
implementing a fifth etching process, which includes: etching to remove the third protection layer, to expose insulating surface of the insulating film layer at a corresponding position originally covered by the third protection layer;
implementing a board removal process, which includes: separating the two metal plates from the adhesive material, to obtain two package substrate semi-finished products;
implementing a third development process, which includes: forming a patterned fourth protection layer on the first surface of the metal plate in the package substrate semi-finished product, and an area covered by the fourth protection layer on the first surface corresponds each of the first openings of the second surface;
implementing a surface treatment process, which includes: forming a patterned surface treatment layer on a metal surface area exposed from the first surface and the second surface;
implementing a sixth etching process, which includes: etching to remove the fourth protection layer, to expose metal surface of the first surface that is not covered by the surface treatment layer on the metal plate; and
implementing a seventh etching process, which includes: etching to remove the metal material of the first surface of the metal plate in an area that is not covered by the surface treatment layer to form a plurality of second openings, wherein a bottom of each of the second openings is connected to a bottom of each of the first openings at its corresponding position, and the insulating film layer filled in each of the first openings is exposed at a bottom of each of the second openings at its corresponding position to obtain a package substrate.

2. The method for manufacturing the package substrate according to claim 1, wherein composition of the first protection layer, the second protection layer or the fourth protection layer is a dry film, a photosensitive resin composition or a photosensitive resin film.

3. The method for manufacturing the package substrate according to claim 1, wherein composition of the third protection layer is copper metal.

4. The method for manufacturing the package substrate according to claim 1, wherein the board removal process further comprises performing a high-temperature baking process or a low-temperature baking process before separating the two metal plates from the adhesive material.

5. The method for manufacturing the package substrate according to claim 1, wherein composition of the surface treatment layer is nickel, palladium, platinum, gold or a combination thereof, or an alloy thereof.
